(19) United States
(12) Patent Application Publication
(10) Pub. No.: US 2008/0285361 A1
(43) Pub. Date: Nov. 20, 2008

(54) Input/output line sense amplifier and semiconductor device having the same

(75) Inventor: Sung Mook Kim, Yongin-si (KR)

Correspondence Address: COOPER & DUNHAM, LLP, 1185 AVENUE OF THE AMERICAS, NEW YORK, NY, 10036, US

(73) Assignee: Hynix Semiconductor Inc.

(21) Appl. No.: 12/004,229

(22) Filed: Dec. 20, 2007

(30) Foreign Application Priority Data
May 17, 2007 (KR) 10-2007-0048336

(51) Int. Cl. G11C 7/10; G11C 7/06

(52) U.S. Cl. 365/189.15; 365/208; 365/193

(57) ABSTRACT

An input/output (I/O) line sense amplifier includes a first sense amplifier configured to amplify a signal of an I/O line in response to a strobe signal, and a second sense amplifier configured to latch and amplify an output signal of the first sense amplifier in response to the strobe signal.

### BACKGROUND

The present disclosure relates to a semiconductor memory device, and more particularly, to an input/output line sense amplifier configured to sense and amplify data of input/output lines and a semiconductor memory device having the same.

In general, data input/output (I/O) lines are used for transferring data in a semiconductor memory device. An output signal of a bit line sense amplifier (BLSA) in a memory cell area (or core area) is transferred to a global I/O line (GIO) via a local I/O line (LIO). In general, the global I/O line is globally disposed over a plurality of banks, and transfers data between a data I/O pad and a memory cell area.

A circuit is required for transferring data between the global I/O line and the local I/O line. In the case of a dynamic random access memory (DRAM), an I/O line sense amplifier (IOSA) is used to amplify data carried on the local I/O line and transfer the amplified data to the global I/O line in a read operation, and a write driver (WDRV) is used to amplify data carried on the global I/O line and transfer the amplified data to the local I/O line in a write operation.

Conventional I/O line sense amplifiers may be divided into a one-stage amplification type and a two-stage amplification type. First, the one-stage amplification type I/O line sense amplifier has a simple circuit configuration, thus contributing to the decrease in current consumption. However, since an offset characteristic of an input signal is deteriorated, a potential difference between data carried on local I/O lines (LIO and LIOB) must reach a predetermined level, e.g., 230 mV or higher, to sufficiently amplify the data and transfer the amplified data to the global I/O line. To this end, it is necessary to delay an activation period of a strobe signal for driving the I/O line sense amplifier by a predetermined time, but in this case, a column address access time (tAA) undesirably increases.

The two-stage amplification type I/O line sense amplifier amplifies data of the local I/O lines (LIO and LIOB) through two-stage amplifications. Two-stage amplification operations are sequentially performed by separate strobe signals, thereby improving offset characteristics of an input signal. Thus, even if the potential difference between data of the local I/O lines LIO and LIOB has a small level, e.g., 100 mV, the data can be sufficiently amplified and transferred to the global I/O line. However, this two-stage amplification type I/O sense amplifier gives a rise to a problem in that unnecessary current consumption inevitably increases for generating two strobe signals. Moreover, such an increase in current consumption makes it difficult to achieve low power consumption in a semiconductor memory device, particularly a portable memory device.

### SUMMARY

The present disclosure describes various examples and embodiments of the present invention. For example, in accordance with an aspect of this disclosure, an input/output (I/O) line sense amplifier is configured to reduce current consumption by amplifying data of local I/O lines (LIO and LIOB) using one strobe signal and then transferring the amplified data to global I/O line (GIO).

In an exemplary embodiment, an I/O line sense amplifier includes a first sense amplifier configured to amplify a signal of an I/O line in response to a strobe signal, and a second sense amplifier configured to latch and amplify an output signal of the first sense amplifier in response to the strobe signal.

The I/O line sense amplifier may further include a strobe signal generator configured to generate the strobe signal for driving the first and second sense amplifiers.

The first sense amplifier may include a differential amplifier configured to differentially amplify the signal of the I/O line, and an enabler configured to enable an operation of the differential amplifier in response to the strobe signal.

The second sense amplifier may include a latch unit configured to latch the output signal of the first sense amplifier, and a drive controller configured to control an operation of the latch unit in response to the strobe signal.

The drive controller may include a MOS transistor configured to control an operating speed of the latch unit by a width-to-length (W/L) ratio.

The second sense amplifier may further include a precharge unit configured to precharge an input signal of the latch unit in response to the strobe signal.

The I/O line sense amplifier may further include a driver configured to drive an output signal of the second sense amplifier.

In another embodiment, a semiconductor memory device includes a memory cell array comprising a bit line sense amplifier, an I/O line sense amplifier configured to amplify a signal of the bit line sense amplifier inputted to a first I/O line and transfer the amplified signal to a second I/O line, the I/O line sense amplifier being driven in response to one strobe signal, and a write driver configured to amplify a signal, which is inputted to a data pad and transferred to the second I/O line, and transfer the amplified signal to the first I/O line.

The I/O line sense amplifier may include a first sense amplifier configured to amplify a signal of the first I/O line in response to the strobe signal, and a second sense amplifier configured to latch and amplify an output signal of the first sense amplifier in response to the strobe signal.

### BRIEF DESCRIPTION OF THE DRAWINGS

FIG. 1 illustrates a block diagram of a semiconductor memory device including an input/output (I/O) line sense amplifier according to an exemplary embodiment of the present invention.

FIG. 2 illustrates a block diagram of a semiconductor memory device including an I/O line sense amplifier according to another exemplary embodiment of the present invention.

FIG. 3 illustrates a circuit diagram of an I/O line sense amplifier that can be included in any of the semiconductor memory devices of FIGS. 1 and 2.

FIGS. 4 to 5 illustrate simulation graphs to compare characteristics of the I/O line sense amplifier according to an embodiment of the present invention with those of the conventional I/O line sense amplifier, under process-voltage-temperature (PVT) condition.

### DESCRIPTION OF EXEMPLARY EMBODIMENTS

Hereinafter, an input/output line sense amplifier and a semiconductor device having the same in accordance with the present invention will be described in detail with reference to the accompanying drawings. The following examples and embodiments merely exemplify the present invention, and hence the scope of the present invention is not limited to the examples and exemplary embodiments.

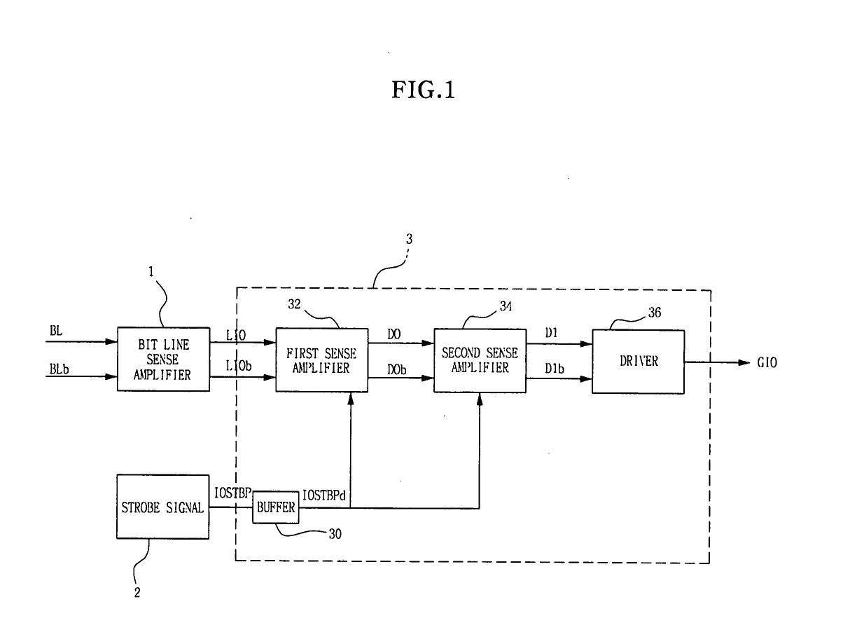

FIG. 1 illustrates a block diagram of a semiconductor memory device including an input/output (I/O) line sense amplifier according to an exemplary embodiment of the present invention.

Referring to FIG. 1, the semiconductor memory device of this embodiment includes a bit line sense amplifier (BLSA) 1, a strobe signal generator 2 and an I/O line sense amplifier (IOSA) 3. The bit line sense amplifier 1 is configured to sense and amplify data of bit lines BL and BLb, and transfer the amplified data to local I/O lines LIO and LIOb. The strobe signal generator 2 is configured to generate a strobe signal IOSTBP. The I/O sense amplifier 3 is configured to amplify signals of the local I/O lines LIO and LIOb and transfer the amplified signal to a global I/O line GIO in response to the strobe signal IOSTBP. Herein, the bit line sense amplifier 1 and the strobe signal generator 2 can be implemented with typical circuits, and thus further detailed description for them will be omitted.

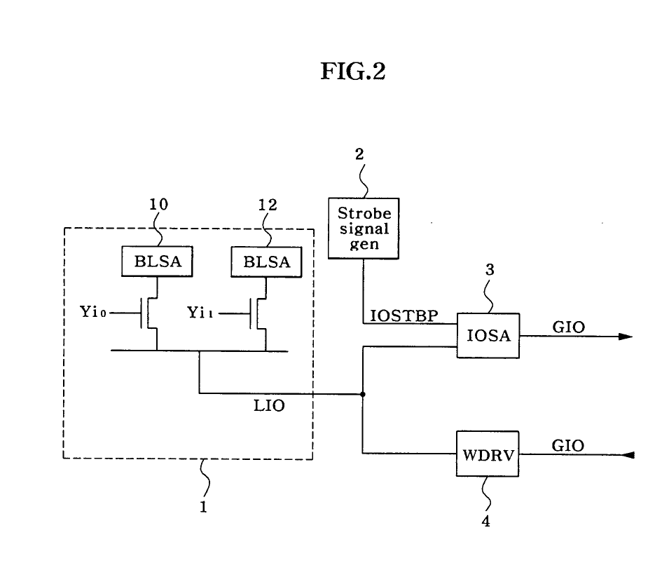

FIG. 2 illustrates a block diagram of a semiconductor memory device including an I/O line sense amplifier according to another exemplary embodiment of the present invention.

Referring to FIG. 2, the semiconductor memory device of this embodiment includes a memory cell array 1, an I/O sense amplifier 3 and a write driver 4. The memory cell array 1 includes bit line sense amplifiers 10 and 12. The I/O sense amplifier 3 is configured to amplify data carried on a local I/O line LIO and transfer the amplified data to a global I/O line GIO in a read operation. The write driver 4 is configured to amplify data carried on the global I/O line GIO and transfer the amplified data to the local I/O line LIO in a write operation. Here, the I/O sense amplifier 3 may further include a signal generator 2 configured to generate a strobe signal IOSTBP.

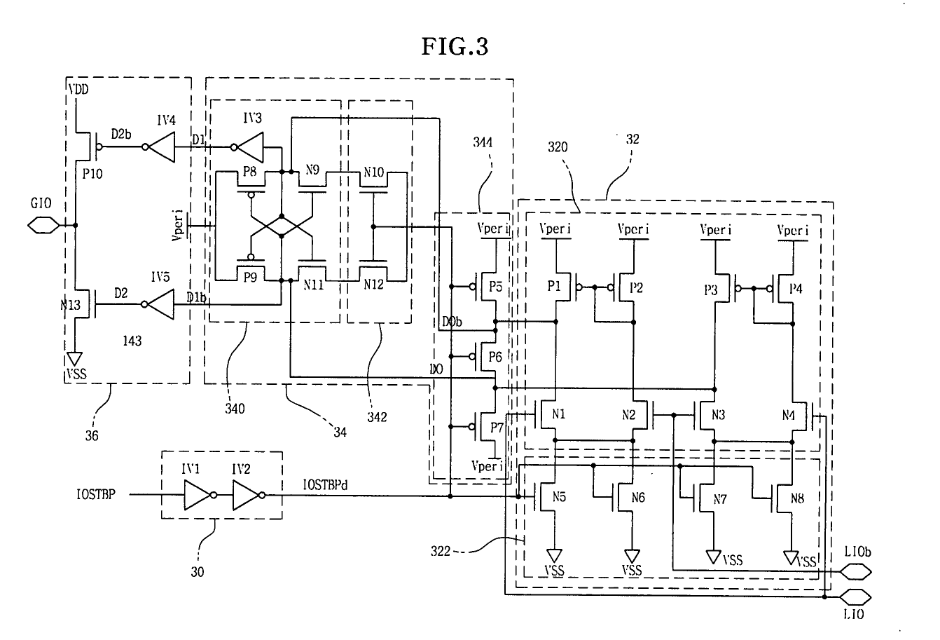

Hereinafter, the I/O sense amplifier 3 included in the semiconductor memory devices of FIGS. 1 and 2 will be more fully described with reference to a circuit diagram of FIG. 3.

Referring to FIG. 3, the I/O sense amplifier 3 includes a buffer 30, a first sense amplifier 32, a second sense amplifier 34 and a driver 36. The buffer 30 is configured to buffer the strobe signal IOSTBP to generate a strobe signal IOSTBPd. The first sense amplifier 32 is configured to receive signals of the local I/O lines LIO and LIOb to differentially amplify the received signals in response to the strobe signal IOSTBPd. The second sense amplifier 34 is configured to latch and amplify an output signal of the first sense amplifier 32 in response to the strobe signal IOSTBPd. The driver 36 is configured to drive an output signal of the second sense amplifier 34 to transfer it to the global I/O line GIO.

The first sense amplifier 32 includes a differential amplifier 320 and an enabler 322. The differential amplifier 320 is configured with two differential amplification circuits. The enabler 322 is configured with NMOS transistors N5-N8 which are configured to enable an operation of the differential amplifier 320. Specifically, the differential amplifier 320 includes PMOS transistors P1-P2 and P3-P4 forming a current mirror, and NMOS transistors N1-N4 which receive signals of the local I/O lines LIO and LIOb. The differential amplifier 320 having the above-described configuration differentially amplifies the signals of the local I/O lines LIO and LIOb to output first amplified signals D0 and D0b.

The second sense amplifier 34 includes a latch unit 340, a drive controller 342 and a precharge unit 344. The latch unit 340 is configured as a cross-coupled amplifier, and latches the first amplified signals D0 and D0b to output second amplified signals D1 and D1b. The driver controller 342 is configured with NMOS transistors N10 and N12 which are configured to enable an operation of the latch unit 340 in response to the strobe signal IOSTBPd. The precharge unit 344 is configured to precharge the first amplified signals D0 and D0b to a level of an internal voltage Vperi in response to the strobe signal IOSTBPd. Herein, if a width-to-length (W/L) ratio of each NMOS transistor N10˜N12 is reduced in some degree, the operation speed of the second sense amplifier 34 increases and current consumption decreases.

The driver 36 includes inverters IV4 and IV5, a PMOS transistor P10 and an NMOS transistor N13. The inverter IV4 is configured to invert and buffer the second amplified signal D1 to generate an inverted signal D2b. Likewise, the inverter IV5 is configured to invert and buffer the second amplified signal D1b to generate an inverted signal D2. The PMOS transistor P10 is configured to pull up the global I/O line GIO to a power supply voltage VDD in response to the inverted signal D2b of the second amplified signal D1. The NMOS transistor N13 is configured to pull down the global I/O line to a ground voltage VSS in response to the inverted signal D2 of the second amplified signal D1b.

An operation of the I/O sense amplifier 3 having the above-described configuration will be described in detail with reference to FIG. 3.

The strobe signal IOSTBP is buffered through the buffer 30. The strobe signal IOSTBPd, which is output by the buffer 30, controls the operations of the first and second sense amplifiers 32 and 34.

First, when the strobe signal IOSTBPd is deactivated to a logic low level, the NMOS transistors N5-N8 included in the enabler 322 of the first sense amplifier 32 are all turned off to stop the operation of the differential amplifier 320. In addition, the strobe signal IOSTBPd of the logic low level turns off the NMOS transistors N10 and N12 included in the drive controller 342 of the second sense amplifier 34. At this time, since each of the PMOS transistors P5-P7 included in the precharge unit 344 of the second sense amplifier 34 is tuned on by the strobe signal IOSTBPd of the logic low level, the first amplified signals D0 and D0b are precharged to a level of the internal voltage Vperi. Although a driving voltage for driving the first and second sense amplifiers 32 and 34 is the internal voltage Vperi in this embodiment, the power supply voltage VDD may be used as the driving voltage according to other embodiments.

When the strobe signal IOSTBPd is activated to a logic high level, each of the NMOS transistors N5-N8 of the enabler 322 and the NMOS transistors N10 and N12 of the drive controller 342 is turned on. Accordingly, the differential amplifier 320 and the latch unit 340 operate to amplify the signals of the local I/O lines LIO and LIOb and then transfers the amplified signals to the global I/O line GIO. Hereinafter, a first amplification stage by the differential amplifier 320 and a second amplification stage by the latch unit 340 will be more specifically described.

For example, when the signal of the local I/O line LIO is at a logic high level and the signal of the local I/O line LIOb is at a logic low level, the differential amplifier 320 differentially amplifies the signals of the local I/O lines LIO and LIOb to output the first amplified signal D0 of a logic high level and the first amplified signal D0b of a logic low level. At this point, the signal of the local I/O line LIO has a voltage level of approximately 50 mV, whereas the first amplified signal D0 has a voltage level of approximately 1,000 mV.

The first amplified signals D0 and D0b, which have been differentially amplified by the differential amplifier 320, are re-amplified through the latch unit 340. That is, the latch unit 340 latches the first amplified signal D0 of a logic high level and the first amplified signal D0b of a logic low level to thereby output the second amplified signals D1 and D1b. Here, the second amplified signals D1 and D1b are high level signals which are amplified to full logic levels.

The driver 36 receives the second amplified signals D1 and D1b from the latch unit 340 to drive the global I/O line GIO. The inverter IV4 inverts the second amplified signal D1 of a logic high level to output the inverted signal D2b of a logic low level. Therefore, the PMOS transistor P10 is turned on to pull up the global I/O line GIO, thereby transferring the signal of the local I/O line LIO of a logic high level. The inverter IV5 inverts the second amplified signal D1b of a logic high level to output an inverted signal D2 of a logic low level, making the NMOS transistor N13 turned off.

As described above, one strobe signal IOSTBPd drives both the first and second sense amplifiers 32 and 34 in the I/O sense amplifier 3 of the exemplary embodiments of FIGS. 1-3. Therefore, compared to the conventional I/O sense amplifier performing the two-stage amplification using the two strobe signals, the I/O sense amplifier 3 can reduce current consumption because it requires only half of the circuit for generating the strobe signal.

Herein, the first and second sense amplifiers 32 and 34 are simultaneously driven in response to the strobe signal IOSTBPd of logic high level but their operations differ from each other. Specifically, the output of the first sense amplifier 32 changes depending on the signals of the local I/O lines LIO and LIOb during the input period of the strobe signal IOSTBPd. However, the second sense amplifier 34 maintains the levels of the second amplified signals D1 and D1b which are determined depending on the levels of the first amplified signals D0 and D0b inputted when the strobe signal IOSTBPd goes to a logic high level. Thus, the second sense amplifier 34 maintains its output signal to a constant level regardless of variation in the levels of the input signals, e.g., the first amplified signals D0 and D0b, while the strobe signal IOSTBPd is maintained at a logic high level. Therefore, although the first and second sense amplifiers 32 and 34 are simultaneously driven when the strobe signal IOSTBPd goes to a logic high level, the second sense amplifier 34 drives the global I/O line GIO depending on the voltage levels of the second amplified signals D1 and D1b determined by the first amplified signals D0 and D0b which are inputted when the strobe signal IOSTBPd goes to a logic high level.

The I/O sense amplifier 3 of the exemplary embodiments of FIGS. 1-3 performs two-stage amplification in sequence by driving the first and second sense amplifiers 32 and 34 not using two separate strobe signals but using one strobe signal IOSTBPd. In the case where the first and second sense amplifiers 32 and 34 are driven by the two separate strobe signals, there must be a predetermined delay time between the first amplification stage by the first sense amplifier 32 and the second amplification stage by the second sense amplifier 34. In contrast, the I/O sense amplifier 3 is configured such that the first amplification stage by the first sense amplifier 32 and the second amplification stage by the second sense amplifier 34 are sequentially performed by one strobe signal, thus reducing a column address access time tAA.

Various process-voltage-temperature (PVT) conditions are defined in Table 1 below. Referring to Table 1, the PVT condition where a temperature is 90° C., VPERI voltage is 1.4 V, and SKEW is slow, is referred to as ‘WORST’, whereas the PVT condition where a temperature is −30° C., VPERI voltage is 2 V, and SKEW is fast, is referred to as ‘FAST’.

TABLE 1

| PVT condition | TEMP(° C.) | VPERI(V) | SKEW |
|---|---|---|---|
| TYPICAL | 25 | 1.8 | typical |
| LOW | 90 | 1.5 | slow |
| LOWC | −30 | 1.5 | slow |
| WORST | 90 | 1.4 | slow |
| WORSTC | −40 | 1.4 | slow |
| SLOW | 90 | 1.6 | slow |
| FAST | −30 | 2 | fast |
| FAST2 | 90 | 2 | fast2 |
| FS3 | −40 | 1.6 | fs3 |
| SF3 | 90 | 2.1 | sf3 |

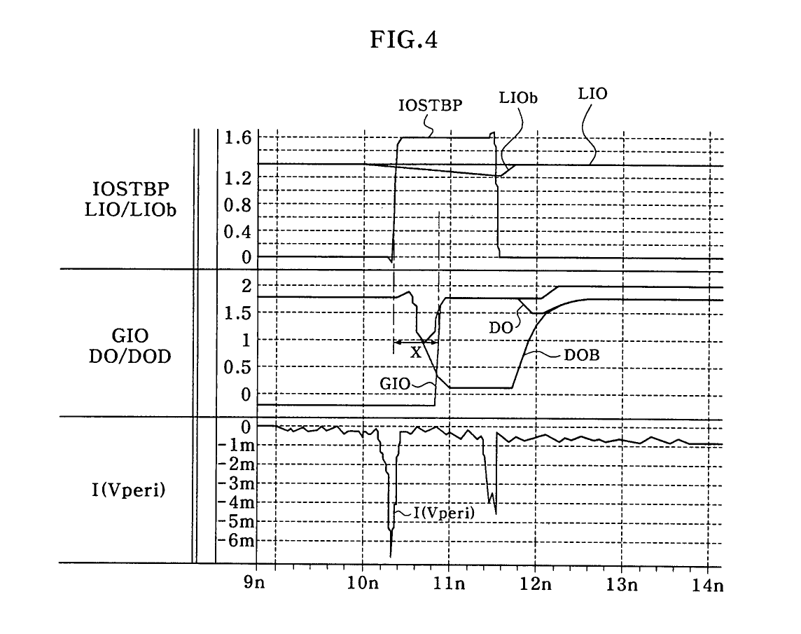

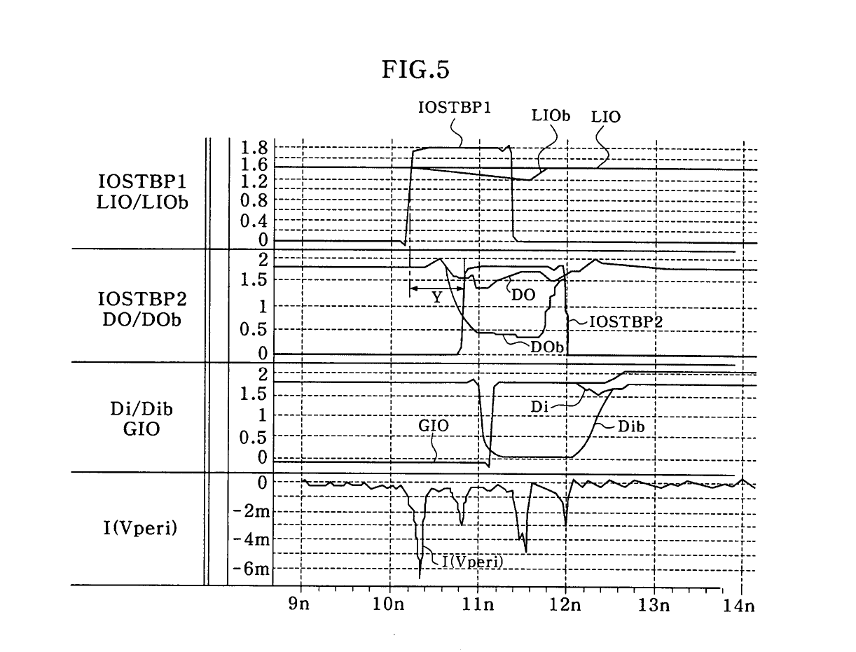

FIG. 4 illustrates a simulation graph of the I/O sense amplifier 3 according to an example wherein the PVT condition corresponds to a ‘TYPICAL’ condition. FIG. 5 illustrates a simulation graph of the conventional I/O sense amplifier when the PVT condition also corresponds to the ‘TYPICAL’ condition.

Comparing the simulation results of FIGS. 4 and 5 with each other, it can be observed that the time ‘stb-gio’ indicated as “X” in FIG. 4, which it takes for the signals of the local I/O lines to be amplified through the two-stage amplification and transferred to the global I/O line GIO, is shorter than the time Y taken in the conventional I/O sense amplifier. In addition, current I(Vperi) consumed when the first and second sense amplifiers 32 and 34 are driven by the internal voltage Vperi is also lower in the present invention than the conventional art.

The following Table 2 sets forth simulation results of the exemplary embodiments of FIGS. 1-3 under various PVT conditions of Table 1. Following Table 3 sets forth simulation results of the conventional art under various PVT conditions of Table 1.

TABLE 2

| | stb-gio | current/IOSA | current/IOSASTB | current/Bank |
|---|---|---|---|---|
| | (ps) | (μA) | (μA) | (mA) |
| TYPICAL | 520 | 252 | 319 | 17 |
| LOW | 707 | 154 | 272 | 10 |
| LOWC | 700 | 152 | 251 | 10 |
| WORST | 842 | 133 | 251 | 9 |
| WORSTC | 851 | 134 | 231 | 9 |
| SLOW | 629 | 177 | 294 | 12 |
| FAST | 248 | 376 | 351 | 25 |
| FAST2 | 335 | 337 | 389 | 22 |
| FS3 | 471 | 220 | 264 | 15 |
| SF3 | 323 | 332 | 409 | 22 |

TABLE 3

| | stb-gio | current/IOSA | current/IOSASTB | current/Bank |
|---|---|---|---|---|
| | (ps) | (μA) | (μA) | (mA) |
| TYPICAL | 781 | 252 | 448 | 17 |
| LOW | 1,380 | 174 | 381 | 12 |
| LOWC | 1,070 | 169 | 354 | 12 |
| WORST | 1,370 | 155 | 353 | 11 |
| WORSTC | 1,340 | 153 | 324 | 10 |
| SLOW | 1,010 | 195 | 412 | 13 |
| FAST | 424 | 749 | 557 | 49 |
| FAST2 | 516 | 304 | 553 | 21 |
| FS3 | 758 | 221 | 374 | 15 |
| SF3 | 562 | 311 | 580 | 21 |

In Tables 2 and 3, the ‘stb-gio’ time, which refers to a time it takes from the activation point of the strobe signal to the driving point of the global I/O line GIO, is a measured value for observing the characteristic of the column address access time tAA. A current/IOSA denotes a current consumed in the I/O sense amplifier, a current/IOSASTB denotes a current consumed in a strobe signal generation circuit, and a current/Bank denotes a current consumed in each bank. Referring to Tables 2 and 3, when employing the I/O sense amplifier of the exemplary embodiments of FIGS. 1-3, it can be observed that the column address access time tAA is reduced by approximately 358.5 ps on the average in comparison with the conventional art, and the current consumed in each bank is reduced by approximately 3 mA on the average.

As described above, the I/O sense amplifier according to the present invention amplifies data of local I/O lines LIO and LIOb through two-stage amplifications using one strobe signal to thereby transfer the amplified data to a global I/O line GIO, which makes it possible to reduce current consumption.

In addition, the I/O sense amplifier of the present invention includes a latch unit driven according to the strobe signal regardless of an input signal, thus reducing a column address access time tAA.

While the present invention has been described with respect to examples and specific embodiments, it will be apparent to those skilled in the art that various changes and modifications may be made without departing from the spirit and scope of the invention as defined in the following claims.

The present application claims priority to Korean patent application number 10-2007-0048336, filed on May 17, 2007, which is incorporated by reference in its entirety.

What is claimed is:

1. An input/output (I/O) line sense amplifier, comprising:
a first sense amplifier configured to amplify a signal of an I/O line in response to a strobe signal; and
a second sense amplifier configured to latch and amplify an output signal of the first sense amplifier in response to the strobe signal.

2. The I/O line sense amplifier of claim 1, further comprising a strobe signal generator configured to generate the strobe signal for driving the first and second sense amplifiers.

3. The I/O line sense amplifier of claim 1, wherein the first sense amplifier comprises:
a differential amplifier configured to differentially amplify the signal of the I/O line; and
an enabler configured to enable an operation of the differential amplifier in response to the strobe signal.

4. The I/O line sense amplifier of claim 1, wherein the second sense amplifier comprises:
a latch unit configured to latch the output signal of the first sense amplifier; and
a drive controller configured to control an operation of the latch unit in response to the strobe signal.

5. The I/O line sense amplifier of claim 4, wherein the drive controller comprises a MOS transistor configured to control an operating speed of the latch unit by a width-to-length (W/L) ratio.

6. The I/O line sense amplifier of claim 4, wherein the second sense amplifier further comprises a precharge unit configured to precharge an input signal of the latch unit in response to the strobe signal.

7. The I/O line sense amplifier of claim 1, further comprising a driver configured to drive an output signal of the second sense amplifier.

8. A semiconductor memory device, comprising:
a memory cell array comprising a bit line sense amplifier;
an I/O sense amplifier configured to amplify a signal of the bit line sense amplifier inputted through a first I/O line and transfer the amplified signal to a second I/O line, the sense amplifier being driven in response to a strobe signal; and
a write driver configured to amplify a signal, inputted through a data pad and transferred to the second I/O line, and transfer the amplified signal to the first I/O line.

9. The semiconductor memory device of claim 8, wherein the I/O sense amplifier comprises:
a first sense amplifier configured to amplify a signal of the first I/O line in response to the strobe signal; and
a second sense amplifier configured to latch and amplify an output signal of the first sense amplifier in response to the strobe signal.

10. The semiconductor memory device of claim 9, wherein the I/O sense amplifier further comprises a strobe signal generator configured to generate the strobe signal for driving the first and second sense amplifiers.

11. The semiconductor memory device of claim 9, wherein the first sense amplifier comprises:
a differential amplifier configured to differentially amplify the signal of the first I/O line; and
an enabler configured to enable an operation of the differential amplifier in response to the strobe signal.

12. The semiconductor memory device of claim 9, wherein the second sense amplifier comprises:
a latch unit configured to latch the output signal of the first sense amplifier; and
a drive controller configured to control an operation of the latch unit in response to the strobe signal.

13. The semiconductor memory device of claim 12, wherein the drive controller comprises a MOS transistor configured to control an operating speed of the latch unit by a width-to-length (W/L) ratio.

14. The semiconductor memory device of claim 12, wherein the second sense amplifier further comprises a precharge unit configured to precharge an input signal of the latch unit in response to the strobe signal.

15. The semiconductor memory device of claim 9, further comprising a driver configured to drive an output signal of the second sense amplifier.

16. The semiconductor memory device of claim 8, wherein the first I/O line is a local I/O line.

17. The semiconductor memory device of claim 8, wherein the second I/O line is a global I/O line.

18. An input/output (I/O) line sense amplifier, comprising:
a strobe signal generator configured to generate a strobe signal;
a first sense amplifier comprising a differential amplifier configured to differentially amplify the signal of an I/O line and an enabler configured to enable an operation of the differential amplifier in response to the strobe signal;
a second sense amplifier comprising a latch unit configured to latch the output signal of the first sense amplifier, a drive controller configured to control an operation of the latch unit in response to the strobe signal and a precharge unit configured to precharge an input signal of the latch unit in response to the strobe signal; and
a driver configured to drive an output signal of the second sense amplifier.

19. The semiconductor input/output (I/O) line sense amplifier of claim 18, wherein the drive controller comprises a MOS transistor configured to control an operating speed of the latch unit by a width-to-length (W/L) ratio.
